(19) United States
(12) Patent Application Publication
(10) Pub. No.: US 2005/0083084 A1
(43) Pub. Date: Apr. 21, 2005

(54) Voltage generating circuit

(75) Inventors: Shinichi Aota, Osaka (JP); Takashi Tsukada, Osaka (JP); Hideki Mine, Osaka (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Toshiba Matsushita Display Technology, Tokyo, (JP)

(21) Appl. No.: 10/503,598

(22) PCT Filed: Oct. 27, 2003
(86) PCT No.: PCT/JP03/13675

(30) Foreign Application Priority Data
Oct. 29, 2002 (JP) 2002-314860

(51) Int. Cl. H03D 3/00

(52) U.S. Cl. 327/39

(57) ABSTRACT

It is necessary to reduce power consumption in a liquid crystal display device.

A drive voltage generation circuit 201 including: a clock signal dividing circuit 204 which applies signal processing, which does not divide a frequency of a clock signal SG₂₂ to be inputted from the outside during a display period T₁₃ for performing basic display for always displaying a radio wave reception state or the like of a cellular phone within a liquid crystal display panel and divides the frequency on the basis of a standard decided in advance during periods other than the display period T₁₃, to a clock signal; and booster circuits 202 and 203 which generate a predetermined voltage for performing basic display for always displaying a radio wave reception state or the like of a cellular phone within the liquid crystal display panel using the clock signal SG₁₃, a frequency of which has been divided by the clock signal dividing circuit 204.

### TECHNICAL FIELD

The present invention relates to a voltage generation circuit which is used for, for example, a display of a notebook personal computer, a personal digital assistant, a television, and the like.

### BACKGROUND ART

In recent years, in accordance with technical innovation of multimedia, improvement in performance of a portable liquid crystal display device represented by a personal digital assistant and a cellular phone is demanded.

Here, with reference to FIGS. 3 and 4, a structure and an operation of a conventional liquid crystal display device (e.g., see Japanese Patent Application Laid-Open Nos. 2001-343921 and 2001-215929) will be described.

The entire disclosures of Japanese Patent Application Laid-Open Nos. 2001-343921 and 2001-215929 are incorporated herein by reference in their entireties.

Note that FIG. 3 is an explanatory diagram for explaining a behavior of a waveform of a conventional clock signal SG₄₂. In addition, FIG. 4 is a configuration diagram of a conventional drive voltage generation circuit 401.

First, with reference mainly to FIG. 4, a structure of the conventional drive voltage generation circuit 401 will be described.

Reference sign SG₄₁ denotes a reference voltage to be inputted from the outside.

Reference sign SG₄₂ denotes a clock signal to be inputted from the outside.

Reference numeral 401 denotes a drive voltage generation circuit, which is a circuit of generating various voltages to be used in a liquid crystal display device from the reference voltage SG₄₁ to be inputted from the outside.

Reference numerals 402 and 403 denote booster circuits, which are circuits having a function of generating various voltages in response to the reference voltage SG₄₁ to be inputted from the outside and the clock signal SG₄₂ to be inputted from the outside and outputting the voltages.

Reference signs SG₄₃ and SG₄₄ denote voltages boosted by the booster circuits 401 and 402, respectively, and are used in the liquid crystal display device.

The reference voltage SG₄₁ and the clock signal SG₄₂, which are inputted to the drive voltage generation circuit 401, are inputted to the booster circuits 402 and 403, respectively, and after being boosted to the various kinds of voltages SG₄₃ and SG₄₄, are used in the liquid crystal display device.

Here, with reference mainly to FIG. 3, a behavior of a waveform of a clock signal during one vertical period in the conventional drive voltage generation circuit 401 will be described.

Reference sign SG₃₁ denotes a V (vertical) synchronizing signal.

Reference sign SG₃₂ denotes a display area signal indicating a start line and an end line of a display area in which a video or an image is displayed on a liquid crystal display panel (not shown).

As described above, reference sign SG₄₂ denotes a clock signal to be inputted to the drive voltage generation circuit 401.

Reference sign T₃₁ denotes one vertical period.

Reference sign T₃₂ denotes a maximum valid display period during which display can be performed on the liquid crystal display panel.

Reference sign T₃₃ denotes a display period during which an image or a video is actually displayed on the liquid crystal display panel. In the case in which only a part of the liquid crystal display panel is used for display, the display period T₃₃ is smaller than the maximum valid display period T₃₂.

Reference sign T₃₄ denotes a V blanking period.

Note that, in this specification, a period during which display is not performed (i.e., a period from a time when a signal indicating an end line of a display area is inputted until a time when a signal indicating a start line of the next display area is inputted) is called the V blanking period.

Next, with reference mainly to FIG. 4, an operation of the conventional drive voltage generation circuit 401 will be described.

The drive voltage generation circuit 401 supplies a specific voltage to the liquid crystal display device using the clock signal SG₄₂ to be inputted to the booster circuits 402 and 403.

Here, the clock signal SG₄₂ is always supplied during the one vertical period T₃₁ (see FIG. 3) regardless of whether the entire liquid crystal display panel is used for display or only a part of the liquid crystal display panel is used for display.

However, a voltage necessary for driving a gate driver (not shown) is smaller in the case in which only a part of the liquid crystal display panel with less number of display lines is used for display than in the case in which the entire liquid crystal display panel is used for display.

Further, for example, in a liquid crystal display panel of a cellular phone, only apart of the liquid crystal display panel is often used for display at such a time when a telephone call is not in progress or the like.

The inventor has discovered that waste of power consumption is caused because a clock signal is always supplied during the one vertical period T₃₁ (see FIG. 3) regardless of the fact that a voltage necessary for driving the gate driver is small, for example, in the case in which only a part of the liquid crystal display panel is used for display.

### DISCLOSURE OF THE INVENTION

Taking into account such conventional problems as described above, it is an object of the present invention to provide, for example, a voltage generation circuit which can further reduce power consumption in a liquid crystal display device.

A first invention of the present invention is a voltage generation circuit comprising:
signal processing means of applying signal processing, which does not divide a frequency of a clock signal to be inputted from the outside during a predetermined period for performing predetermined display within a liquid crystal display panel and divides the frequency on the basis of a standard decided in advance during periods other than said predetermined period, to said clock signal; and
voltage generating means of generating a predetermined voltage for performing said predetermined display within said liquid crystal display panel using the clock signal to which said signal processing has been applied.

A second invention of the present invention is the voltage generation circuit according to the first present invention,
wherein dividing a frequency on the basis of said standard decided in advance means dividing a frequency such that said divided frequency is equal to or higher than a predetermined value.

A third invention of the present invention is the voltage generation circuit according to the first present invention,
wherein said predetermined display to be performed within said liquid crystal display panel is display to be performed within a part of said liquid crystal display panel on the basis of a predetermined instruction.

A fourth invention of the present invention is the voltage generation circuit according to the first present invention,
wherein said predetermined period is a display period.

A fifth invention of the present invention is the voltage generation circuit according to the first present invention,
wherein said liquid crystal display panel has plural pixels which are arranged in association with crossing portions of plural columns of source lines and plural rows of gate lines, and
the predetermined voltage for performing said predetermined display within said liquid crystal display panel means a source line drive voltage for driving said plural columns of source lines and a gate line drive voltage for driving said plural rows of gate lines.

A sixth invention of the present invention is a liquid crystal display device comprising:
the voltage generation circuit according to the fifth present invention;
a source drivers of driving said plural columns of source lines using said source line drive voltage; and
a gate driver of driving said plural rows of gate lines using said gate line drive voltage.

A seventh invention of the present invention is a voltage generation method comprising:
a signal processing step of applying signal processing, which does not divide a frequency of a clock signal to be inputted from the outside during a predetermined period for performing predetermined display within a liquid crystal display panel and divides the frequency on the basis of a standard decided in advance during periods other than said predetermined period, to said clock signal; and
a voltage generation step of generating a predetermined voltage for performing said predetermined display within said liquid crystal display panel using the clock signal to which said signal processing has been applied.

An eighth invention of the present invention is a program of causing a computer to execute the signal processing step of applying signal processing, which does not divide a frequency of a clock signal to be inputted from the outside during a predetermined period for performing predetermined display within a liquid crystal display panel and divides the frequency on the basis of a standard decided in advance during periods other than the predetermined period, to the clock signal; and the voltage generation step of generating a predetermined voltage for performing the predetermined display within the liquid crystal display panel using the clock signal to which the signal processing has been applied, of the voltage generation method according to the seventh present invention.

A ninth invention of the present invention is a recording medium carrying the program according to the eighth present invention and is a recording medium which can be processed by the computer.

### BRIEF DESCRIPTION OF THE DRAWINGS

FIG. 1 is an explanatory diagram for explaining a behavior of a waveform of a clock signal SG₁₃, a frequency of which has been divided by a clock signal dividing circuit 204 of a first embodiment of the present invention;

FIG. 2 is a configuration diagram of a drive voltage generation circuit 201 of the first embodiment of the present invention;

FIG. 3 is an explanatory diagram for explaining a behavior of a waveform of a conventional clock signal SG₄₂;

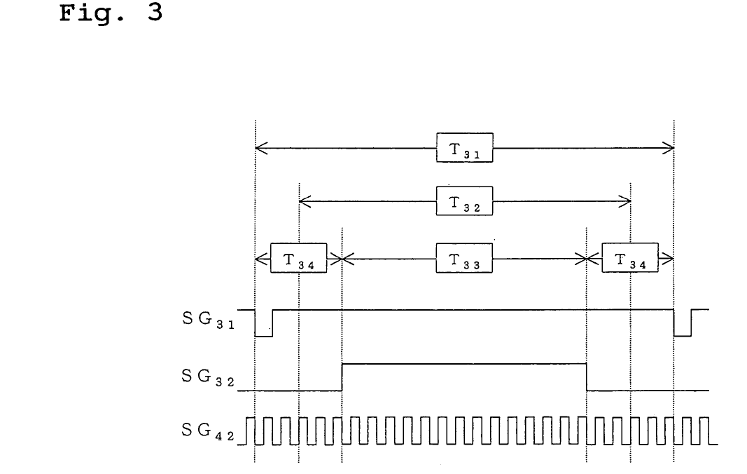

FIG. 4 is a configuration diagram of a conventional drive voltage generation circuit 401;

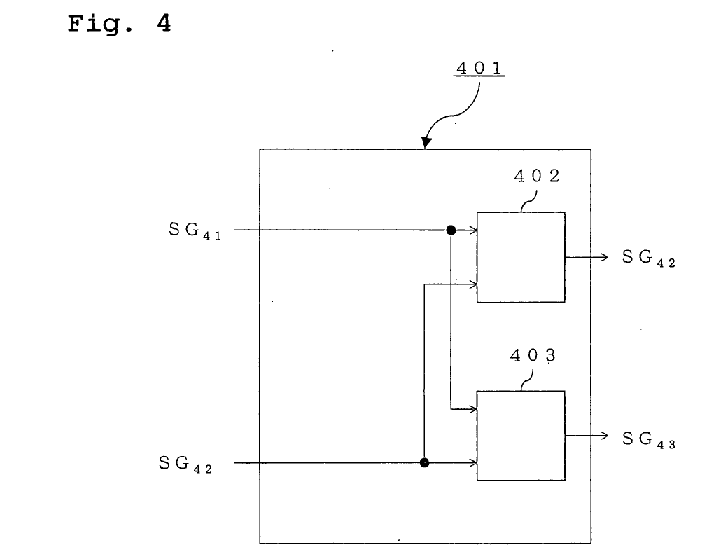

FIG. 5 is a configuration diagram of a liquid crystal display device of an embodiment of the present invention;

FIG. 6 is an explanatory diagram of a circuit arrangement in circuit packaging of the liquid crystal display device of the embodiment of the present invention; and

FIG. 7 is an explanatory diagram of a voltage doubler converter of the first embodiment of the present invention.

### DESCRIPTION OF SYMBOLS

SG₁₁ V synchronizing signal
SG₁₂ Display area signal
SG₁₃ Clock signal, a frequency of which has been divided by a clock signal dividing circuit 204
T₁₁ One vertical period
T₁₂ Valid display period during which an image or a video can be displayed on a liquid crystal display panel
T₁₃ Display period during which an image or a video is actually displayed on the liquid crystal display panel
T₁₄ V blanking period
201 Drive voltage generation circuit
202, 203 Booster circuits
204 Clock signal dividing circuit
SG₂₁ Reference voltage to be inputted from the outside
SG₂₂ Clock signal to be inputted from the outside
SG₂₃, SG₂₄ Output voltage
SG₃₁ V synchronizing signal
SG₃₂ Display area signal
T₃₁ One vertical period
T₃₂ Valid display period during which an image or a video can be displayed on a liquid crystal display panel
T₃₃ Display period during which an image or a video is actually displayed on the liquid crystal display panel
T₃₄ V blanking period
401 Drive voltage generation circuit
402, 403 Booster circuits
SG₄₁ Reference voltage to be inputted from the outside
SG₄₂ Clock signal to be inputted from the outside
SG₄₃, SG₄₄ Output voltages

### BEST MODE FOR CARRYING OUT THE INVENTION

Embodiments of the present invention will be hereinafter described with reference to the drawings.

### FIRST EMBODIMENT

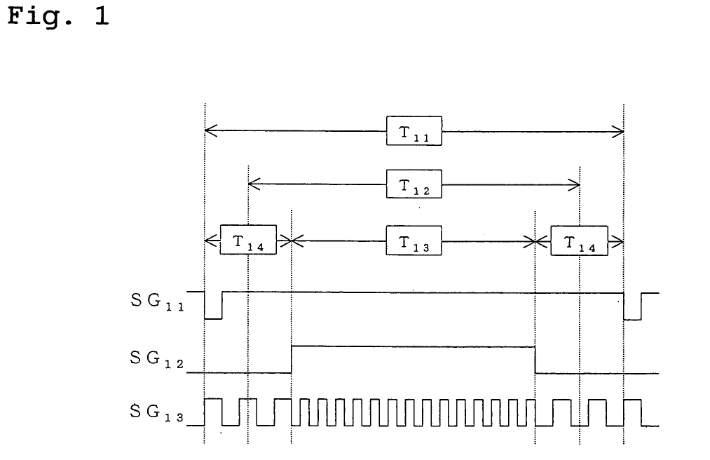

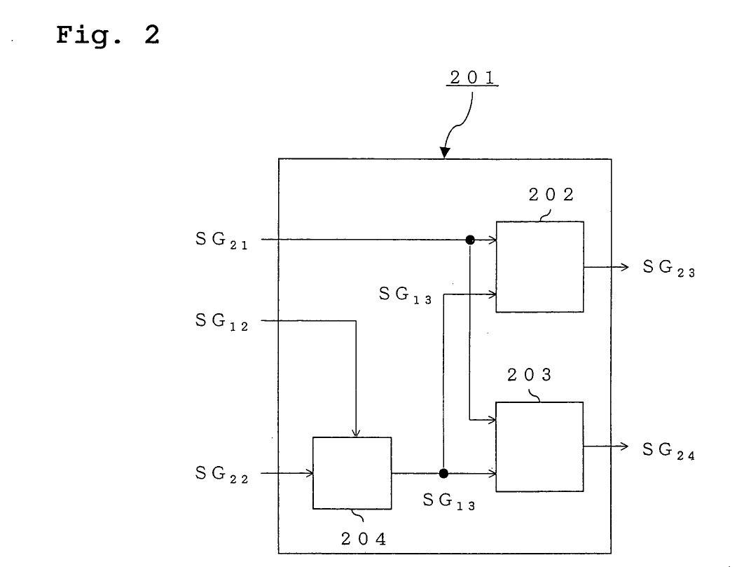

First, with reference to FIGS. 1 and 2, a structure of a drive voltage generation circuit 201 of this embodiment will be described.

Note that FIG. 1 is an explanatory diagram for explaining a behavior of a waveform of a clock signal SG₁₃, a frequency of which has been divided by a clock signal dividing circuit 204 of the first embodiment of the present invention. In addition, FIG. 2 is a configuration diagram of the drive voltage generation circuit 201 of the first embodiment of the present invention.

First, with reference mainly to FIG. 2, a structure of a structure of the drive voltage generation circuit 201 of this embodiment will be described.

Reference sign SG₂₁, denotes a reference voltage to be inputted from the outside.

Reference sign SG₂₂ denotes a clock signal to be inputted from the outside.

Reference signs SG₂₃ and SG₂₄ denote output voltages.

Reference sign SG₁₂ denotes a display area signal indicating a start line and an end line of a display area in which a video or an image is displayed on a liquid crystal display panel (not shown) for a cellular phone having plural pixels, which are arranged in association with crossing portions of plural columns of source lines and plural rows of gate lines.

Reference numeral 201 denotes a drive voltage generation circuit, which is a circuit of generating various voltages such as (1) a source line drive voltage for driving the plural columns of source lines and (2) gate line drive voltage for driving the plural rows of gate lines, which are used in a liquid crystal display device, from the reference voltage SG₂₁ inputted from the outside.

Reference numerals 202 and 203 denote booster circuits, which are circuits having a function of generating various voltages in response to the reference voltage SG₂₁ and the clock signal SG₁₃, a frequency of which has been divided by the clock signal dividing circuit 204, and outputting the voltages.

As described later in detail, this embodiment is characterized in that such generation and output of various voltages are performed using the clock signal SG₁₃ (see FIG. 1) , a frequency of which has been divided by the clock signal dividing circuit 204, rather than the clock signal SG₂₂ itself to be inputted from the outside.

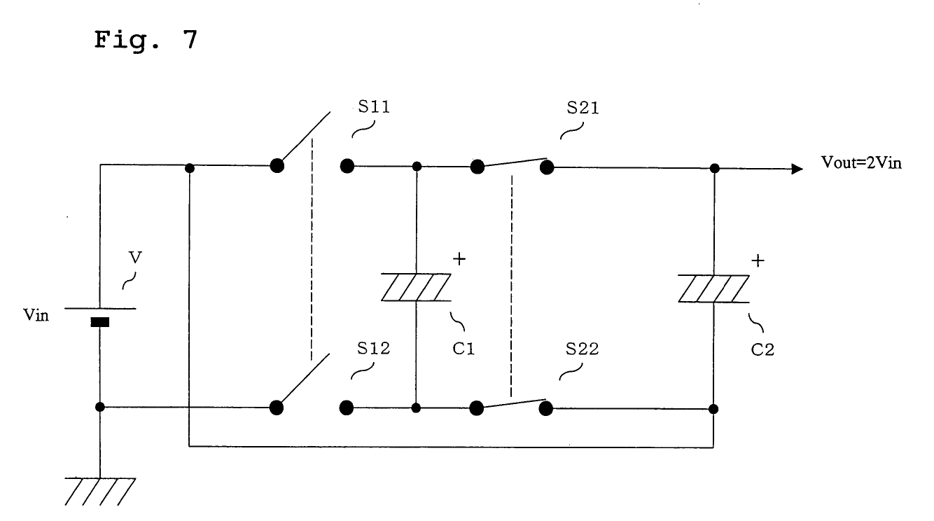

Note that the generation of various voltages can be performed using a so-called principle of a charge pump as shown in FIG. 7 which is an explanatory diagram of a voltage doubler converter of the first embodiment of the present invention.

More specifically, (1) after turning ON switches S₁₁ and S₁₂ and turning OFF switches S₂₁ and S₂₂ to charge a capacitor C₁, (2) by turning OFF the switches S₁₁ and S₁₂ and turning ON the switches S₂₁, and S₂₂ to charge a capacitor C₂, a voltage Vₒᵤₜ=2Vᵥᵢₙ, which is twice as large as a voltage Vᵢₙ of a power supply V, can be obtained.

Reference numeral 204 denotes a clock signal dividing circuit, which is a circuit of dividing a frequency of the clock signal SG₂₂, which has been inputted to the drive voltage generation circuit 201, using the display area signal SG₁₂.

Here, with reference mainly to FIG. 1, a behavior of a waveform of a clock signal during one vertical period in the drive voltage generation circuit 201 of this embodiment will be described.

Reference sign SG₁₁ denotes a V (vertical) synchronizing signal.

Reference sign SG₁₂ denotes, as described above, a display area signal indicating a start line and an end line of a display area in which a video or an image is displayed on a liquid crystal display panel (not shown).

Reference sign SG₁₃denotes a clock signal, a frequency of which has been divided by the clock signal dividing circuit 204.

Reference sign T₁₁ denotes one vertical period.

Reference sign T₁₂ denotes a maximum valid display period during which display can be performed on the liquid crystal display panel.

Reference sign T₁₃ denotes a display period during which an image or a video is actually displayed on the liquid crystal display panel. The display period T₁₃ becomes smaller than the maximum valid display period T₁₂, for example, in the case in which basic display for always displaying a radio wave reception state or the like of a cellular phone is performed only within a basic display part of the liquid crystal display panel.

Reference sign T₁₄ denotes a V blanking period.

Note that means including the clock signal dividing circuit 204 corresponds to signal processing means of the present invention, means including the booster circuits 202 and 203 corresponds to voltage generating means of the present invention, and means including the drive voltage generation circuit 201 corresponds to a voltage generation circuit of the present invention. In addition, the clock signal GS₂₂ to be inputted from the outside corresponds to a clock signal to be inputted from the outside of the present invention, and the clock signal SG₁₃, a frequency of which has been divided by the clock signal dividing circuit 204, corresponds to a clock signal, to which the signal processing has been applied, of the present invention. Further, the basic display for always displaying a radio wave reception state or the like of a cellular phone corresponds to a predetermined display of the present invention. Moreover, the display period T₁₃ corresponds to a predetermined period for performing predetermined display within the liquid crystal display panel of the present invention.

Next, with reference mainly to FIG. 2, an operation of the drive voltage generation circuit 201 of this embodiment will be described.

Note that an embodiment of a drive voltage generation method of the present invention will also be described while the operation of the drive voltage generation circuit 201 of this embodiment is described.

The clock signal dividing circuit 204 generates the clock signal SG₁₃ to be inputted to the booster circuits 202 and 203 using division of a frequency of the clock signal SG₂₂ based upon the display area signal SG₁₂.

More specifically, looking at the display area signal SG₁₂, the clock signal dividing circuit 204 (1) generates the clock signal SG₁₃ without dividing a frequency of the clock signal SG₂₂ to be inputted from the outside in the display period T₁₃ (see FIG. 1) corresponding to a period from a display start line to a display end line in the one vertical period T₁₁ (see FIG. 1) , and (2) generates the clock signal SG₁₃ by dividing a frequency of the clock signal SG₂₂ to be inputted from the outside at a division ratio 1/2 (i.e., dividing the frequency into two) in the V blanking period T₁₄ corresponding to the other periods.

The booster circuits 202 and 203 convert the reference voltage SG₂₁ into a desired voltage using the clock signal G₁₃, a frequency of which has been divided by the clock signal dividing circuit 204 and generates various voltages to be used in the liquid crystal display device.

The drive voltage generation circuit 201 repeats such an operation to thereby supply the various voltages to the liquid crystal display device.

Consequently, the frequency of the clock signal SG₂₂ to be inputted from the outside is switched between the display period T₁₃ and the V blanking period T₁₄ to generate the clock signal SG₁₃, whereby it becomes possible to supply an optimal voltage depending upon a display area and reduce unnecessary power consumption in the entire liquid crystal display device.

The first embodiment has been described in detail.

(A) Note that the predetermined period of the present invention is the display period T₁₃ in the above-described embodiment.

However, the predetermined period of the present invention is not limited to this but, in short, may be any period which is a period for performing predetermined display within the liquid crystal display panel.

(B) In addition, the predetermined display of the present invention is the basic display for always displaying a radio wave reception state or the like of a cellular phone in the above-described embodiment.

However, the predetermined display of the present invention is not limited to this but, in short, may be any display which is performed within a part of the liquid crystal display panel on the basis of a predetermined instruction.

(C) In addition, the signal processing means of the present invention is the means including the clock signal dividing circuit 204 in the above-described embodiment.

However, the signal processing means of the present invention is not limited to this but may be, for example, means including bit clock signal dividing circuits which are arranged for each of plural booster circuits in a drive voltage generation circuit.

In short, the signal processing means of the present invention maybe any means which applies signal processing, which does not divide a frequency of a clock signal to be inputted from the outside during a predetermined period for performing predetermined display within a liquid crystal display panel and divides the frequency on the basis of a standard decided in advance during periods other than the predetermined period, to the clock signal.

(D) In addition, the division of a frequency of the present invention is performed using the division ratio of 1/2 in the above-described embodiment.

However, the division of frequency of the present invention is not limited to this but (1) may be performed using division ratios other than 1/2 or (2) maybe performed using a variable division ratio which is changed appropriately according to predetermined display to be performed.

More specifically, signal processing, which does not divide a frequency of a clock signal of 18 kHz in a display period for performing partial display within the liquid crystal display panel and divides the frequency using a division ratio of 1/4 in a V blanking period, is actually used.

In short, the division of a frequency of the present invention only has to be performed on the basis of a standard decided in advance.

Note that the division of a frequency of the present invention is desirably performed such that a divided frequency is equal to or higher than a predetermined value.

This is because, if the divided frequency is too small, a change in a frequency at a transitioning point of a frequency such as a boundary between the display period T₁₃ (see FIG. 1) and the V blanking period T₁₄ (see FIG. 1) becomes too large, and switching of a frequency becomes difficult.

It is needless to mention that, since it is more convenient for reduction of power consumption in a gate driver or the like if a divided frequency is smaller, it is desirable that the division of a frequency of the present invention is performed such that a divided frequency is not too large or too small.

Therefore, the voltage generation circuit in the present invention is different from a voltage generation circuit (e.g., see Japanese Patent application Laid-Open No. 11-184434) to which, in performing partial display, a clock, which is the same as a frequency of a clock signal to be supplied from the outside, is given in an image data signal ON period, and a clock is not given at all in an image data signal OFF period.

The entire disclosure of Japanese Patent Application Laid-Open No. 11-184434 is incorporated herein by reference in its entirety.

(E) In addition, the predetermined period of the present invention is the display period T₁₃ in the above-described embodiment.

However, the predetermined period of the present invention is not limited to this but may be a period including the display period T₁₃.

More specifically, the predetermined period of the present invention may be a period combining the display period T₁₃ and a so-called approach run period provided in a front part of the display period T₁₃ such that disturbance of display at a transitioning point of a frequency is reduced.

(F) In addition, the voltage generation means of the present invention is the means including the booster circuits 202 and 203 in the above-described embodiment.

However, the voltage generation means of the present invention is not limited to this but, in short, may be any means which generates a predetermined voltage for performing the predetermined display within the liquid crystal display panel using a clock signal to which the signal processing has been applied.

(G) In addition, the predetermined voltage of the present invention is the source line drive voltage for driving plural columns of source lines and the gate line drive voltage for driving plural rows of gate lines in the above-described embodiment.

However, the predetermined voltage of the present invention is not limited to this but, in short, may be any voltage for performing predetermined display within the liquid crystal display panel.

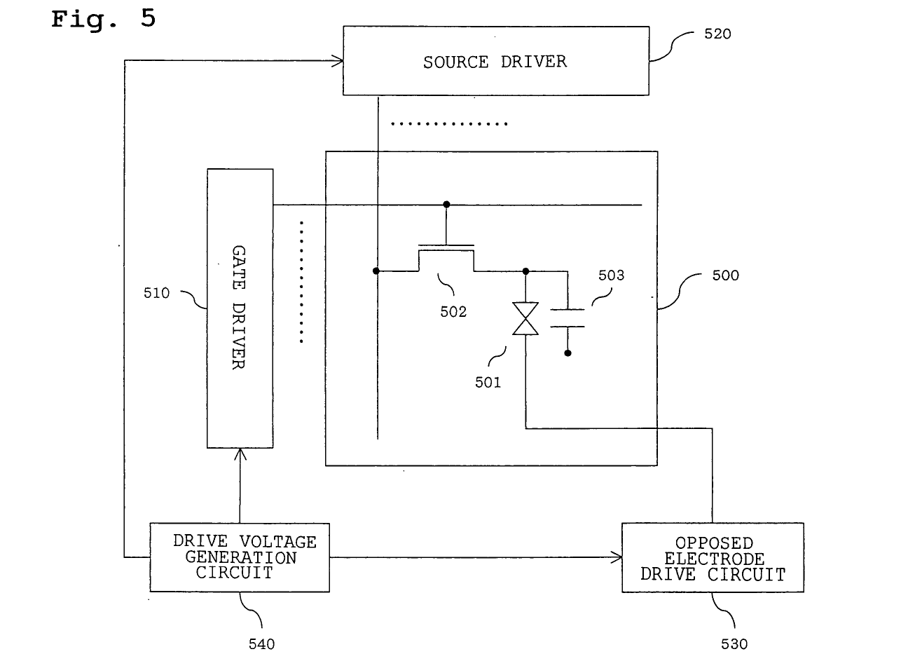

(H) The liquid crystal display device may be a liquid crystal display device, as shown in FIG. 5 which is a configuration diagram of the liquid crystal display device of the embodiment of the present invention, which includes: (1) a liquid crystal display panel 500 including plural pixels 501 which are arranged at points where plural gate lines and plural source lines arranged in a matrix shape cross each other, a switching element 502 which, when a source line forming each of the pixels 501 is selected, transmits a write charge on a corresponding gate line to a pixel electrode, and a storage capacitor 503 holding a write charge; (2) a gate driver 510 of driving a gate line; (3) a source driver 520 of driving a source line; (4) an opposed electrode drive circuit 530 of driving opposed electrodes of each of the pixels 501; and (5) a drive voltage generation circuit (DC/DC) 540 of generating drive voltages for driving the gate driver 510, the source driver 520, and the opposed electrode drive circuit 530, respectively.

Here, the drive voltage generation circuit 540 is a circuit which, in the case in which an image is displayed between arbitrary continuous gate lines in the liquid crystal display panel 500, generates drive voltages, respectively, without dividing a cycle of a clock signal to be inputted in a predetermined period during a one vertical period necessary for display, and generates drive voltages, respectively, by dividing a cycle of the clock signal into n (n is an arbitrary positive number equal to or more than 2) in periods other than the predetermined period in the one vertical period unnecessary for display.

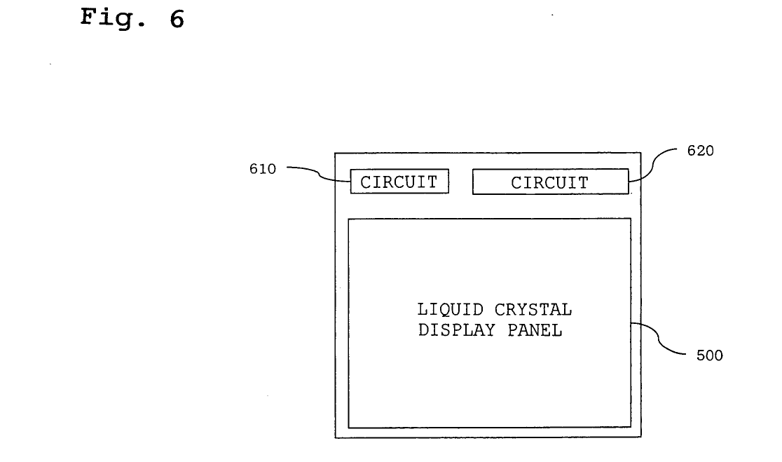

In addition, circuit packaging in which, as shown in FIG. 6 which is an explanatory diagram of a circuit arrangement in circuit packaging in the liquid crystal display device of the embodiment of the present invention, a circuit 610 including a gate driver 510 and a drive voltage generation circuit 540 and a circuit 620 including a source driver 520 and a controller are arranged side by side above the liquid crystal display panel 500 is actually used.

(I) In addition, the program of the present invention is a program of causing a computer to execute an operation of all or apart of steps (or processes, operations, actions, etc.) of the above-described voltage generation method of the present invention and is a program which operates in cooperation with the computer.

In addition, the recording medium of the present invention is a recording medium carrying a program of causing a computer to execute all or a part of an operation of all or part of steps (or processes, operations, actions, etc.) of the above-described voltage generation method of the present invention and is a recording medium which is readable by the computer and, the program read from which executes the operation in cooperation with the computer.

Note that the above-described “part of steps (or processes, operations, actions, etc.)” of the present invention means one or several steps in those plural steps.

In addition, the above-described “operation of steps (or processes, operations, actions, etc.)” of the present invention means all or a part of an operation of the steps.

In addition, a usage pattern of the program of the present invention may be a pattern in which the program is recorded in a computer readable recording medium and cooperates with the computer to operate.

Further, a usage pattern of the program of the present invention may be a pattern in which the program transmits through a transmission medium, is read by a computer, and cooperates with the computer to operate.

Moreover, as the recording medium, a ROM or the like is included, and as the transmission medium, a transmission medium such as the Internet, light, radio wave, sound wave, and the like are included.

Furthermore, the above-described computer of the present invention is not limited to absolute hardware such as a CPU but may include firmware, OS, and peripheral apparatuses.

Note that, as described above, the constitution of the present invention maybe realized in terms of software or may be realized in terms of hardware.

Industrial Applicability.

As it is evident from the above description, the present invention has an advantage that power consumption in a liquid crystal display device can be further reduced.

1. A voltage generation circuit comprising:
means of applying signal processing, which does not divide a frequency of a clock signal to be inputted from the outside during a predetermined period for performing predetermined display within a liquid crystal display panel and divides the frequency on the basis of a standard decided in advance during periods other than said predetermined period, to said clock signal; and
means of generating a predetermined voltage for performing said predetermined display within said liquid crystal display panel using the clock signal to which said signal processing has been applied.

2. The voltage generation circuit according to claim 1,
wherein the dividing a frequency on the basis of said standard decided in advance divides a frequency such that said divided frequency is equal to or higher than a predetermined value.

3. The voltage generation circuit according to claim 1,
wherein said predetermined display to be performed within said liquid crystal display panel is display to be performed within a part of said liquid crystal display panel on the basis of a predetermined instruction.

4. The voltage generation circuit according to claim 1,
wherein said predetermined period is a display period.

5. The voltage generation circuit according to claim 1,
wherein said liquid crystal display panel has plural pixels which are arranged in association with crossing portions of plural columns of source lines and plural rows of gate lines, and
the predetermined voltage for performing said predetermined display within said liquid crystal display panel is a source line drive voltage for driving said plural columns of source lines and a gate line drive voltage for driving said plural rows of gate lines.

6. A liquid crystal display device comprising:
the voltage generation circuit according to claim 5;
a source driver configured to drive said plural columns of source lines using said source line drive voltage; and
a gate driver configured to drive said plural rows of gate lines using said gate line drive voltage.

7. A voltage generation method comprising:
applying signal processing, which does not divide a frequency of a clock signal to be inputted from the outside during a predetermined period for performing predetermined display within a liquid crystal display panel and divides the frequency on the basis of a standard decided in advance during periods other than said predetermined period, to said clock signal; and
generating a predetermined voltage for performing said predetermined display within said liquid crystal display panel using the clock signal to which said signal processing has been applied.

8. A computer program causing a computer to execute:
signal processing, which does not divide a frequency of a clock signal to be inputted from the outside during a predetermined period for performing predetermined display within a liquid crystal display panel and divides the frequency on the basis of a standard decided in advance during periods other than the predetermined period, to the clock signal; and
generating a predetermined voltage for performing the predetermined display within the liquid crystal display panel using the clock signal to which the signal processing has been applied.

9. A recording medium carrying the computer program according to claim 8, the recording medium configured to be processed by the computer.
